(19) United States
(12) Patent Application Publication
(10) Pub. No.: US 2025/0055418 A1
(43) Pub. Date: Feb. 13, 2025

(54) PROCESS AND DEVICE FOR TRACKING MAXIMUM POWER POINT AND MONITORING DEGRADATION OF A PHOTOVOLTAIC MODULE

(71) Applicants: ELECTRICITE DE FRANCE, PARIS (FR); INSTITUT PHOTOVOLTAIQUE D'ILE DE FRANCE (IPVF), PALAISEAU (FR); TOTALENERGIES ONETECH, COURBEVOIE (FR); CENTRE NATIONAL DE LA RECHERCHE SCIENTIFIQUE - CNRS -, PARIS (FR); ECOLE POLYTECHNIQUE, PALAISEAU (FR)

(72) Inventors: Jean-Baptiste PUEL, PARIS (FR); Arthur JULIEN, PARIS (FR); Jean-François GUILLEMOLES, PARIS (FR)

(73) Assignees: ELECTRICITE DE FRANCE, PARIS (FR); INSTITUT PHOTOVOLTAIQUE D'ILE DE FRANCE (IPVF), PALAISEAU (FR); TOTALENERGIES ONETECH, COURBEVOIE (FR); CENTRE NATIONAL DE LA RECHERCHE SCIENTIFIQUE - CNRS -, PARIS (FR); ECOLE POLYTECHNIQUE, PALAISEAU (FR)

(21) Appl. No.: 18/722,945

(22) PCT Filed: Dec. 16, 2022
(86) PCT No.: PCT/EP2022/086289

§ 371 Date: Jun. 21, 2024

(30) Foreign Application Priority Data
Dec. 22, 2021 (FR) 2114289

(51) Int. Cl. H02S 50/10; G01R 21/06

(52) U.S. Cl. CPC H02S 50/10; G01R 21/06

(57) ABSTRACT

A process for maximum power point tracking of a photovoltaic module, which includes monitoring the module's degradation by: for a periodicity n₁δt₀ with n₁>1 constant or variable, steps of measuring parameters I and V of the module for points offset in voltage voltage V_{MPP}+α and V_{MPP}−β over the curve I(V) relative to the maximum power point MPP, calculating the slope dI/dV+ at the point V_{MPP}+α and the slope dI/dV− at the point and V_{MPP}−β and recording of the data with the MPP; for a periodicity n₂δt₀ with n₂≥n₁ of > of steps of measuring values I and V by sweeping the curve I(V) and calculating and storing the module's parameters and values; one or several steps of calculating, tracing and displaying of (p/2)

curves of data pairs based on p measured and calculated parameters; and one or more steps of detecting degradation from the measured and calculated parameters.

### FIELD

The present disclosure comes from the field of management and operation of photovoltaic modules such as photovoltaic panels or sets of panels.

### BACKGROUND

Using maximum power point tracking (MPPT) devices for mono-junction or multi-junction photovoltaic modules is known. These MPPT devices are used on photovoltaic installations such as a solar farm, on roofs or elsewhere. They are in particular suited to monofacial or bifacial photovoltaic modules.

It is also known that materials making up different subcells of a mono-junction or multi-junction module can degrade over time.

Silicon cells are now a mature technology which has benefited from decades of research for increasing the reliability thereof. Such cells may however now be combined with perovskite cells, for which one of the challenges remains the stability over time of the materials from which they are formed. It is therefore necessary to be able to track the degradation thereof and know the causes of this degradation and the distribution over time and frequency thereof.

In the case in particular of cells combining for example silicon junctions with perovskite junctions, it is more specifically necessary to know the causes of degradations of the materials of the junctions causing a loss of yield of the modules and thus plan the necessary improvements for improving these technologies. It is also desirable in the context of the operation of photovoltaic modules to be able to do early detection of anomalies in order to anticipate the replacement of defective modules during favorable windows and thereby avoid periods of unavailability. The performance of the modules under real conditions whether they are in a photovoltaic field or on a roof are specifically affected by these degradation mechanisms. Even though tracking of the power produced by the modules is done to verify the performance thereof over their life, this tracking does not allow understanding in real time what degradation mechanism is involved. Such information is also precious for module manufacturers in order to get an improved understanding of the technology and development thereof over time.

It is therefore not possible to plan the necessary improvements or even to do early detection of anomalies by anticipating the replacement of defective modules during a favorable window because the solutions proposed in the state-of-the-art allow tracking of the power produced and therefore of the worsening of the power but do not allow identification of the causes.

### SUMMARY

The present disclosure aims to improve the situation and allow researching the causes of decreased yield of the modules and improving the tracking of the performance and of the degradation of photovoltaic modules.

To do this, the present disclosure relates to a process for maximum power point tracking of at least one photovoltaic module, comprising, according to a periodicity δt₀, of the I/V operating point measurements of said module and positioning of said operating point at the maximum power point MPP thereof and which comprises a monitoring of the degradation of said module, where said monitoring comprises:
according to a periodicity n₁δt₀ with n₁>1 constant or variable, steps of measurement of the parameters I and V of said module for points offset in voltage V_{MPP}+α and V_{MPP}−β over the curve I(V) relative to the maximum power point MPP, a calculation of the slope dI/dV+ at the point V_{MPP}+α and of the slope dI/dV− at the point V_{MPP}−β and recording of said data along with the MPP;
according to a periodicity n₂δt₀ with n₂≥n₁>of steps of measurement of values of I and V by sweeping the curve I(V) and calculation of parameters (Jsc, Voc, FF, Rs, Rsh, I0, n) of the module and storage of said parameters and values;
one or several steps of calculation, tracing and display of curves according to

$$( \begin{matrix}p \\ 2\end{matrix} )$$

data pairs based on p measured and calculated parameters;
one or more steps of detecting degradation from said measured and calculated parameters.

According to this process, the parameters measured during a lifespan of the monitored module(s) are used for comparison with degradation models for determining the type of degradation occurring and informing the operators of the status of these modules.

At least some parameters p come from calculation of derivatives d[X]/d[Y] with X=[performance and degradation indicator] and Y=[meteorological data for the site], said performance and degradation indicator comprising Efficiency, Jsc, Voc, Impp, Vmpp, FF, Rs, Rsh, dI/dV+, and dI/dV−, and said “meteorological data” comprising: humidity, environmental and module temperature, wind speed, pressure, UV index, and irradiance by means of dedicated meteorological sensors communicating, and the display of said derivatives.

This type of calculation allows consideration of meteorological data for refining the detection of defects.

The values of α and β are advantageously adjusted according to the number of cells of the module(s) included in said measurement steps.

This way single multi-cell modules or sets of modules in series or in parallel can be connected to a single monitoring device.

The process may comprise a modification of the values n₁ and/or n₂ during said monitoring.

Notably, the values n₁ and/or n₂ are reduced during detection of a degradation and in the absence of detection of development of the degradation, the values n₁ and/or n₂ are increased with each loop of the algorithm.

This way the periodicity of the measurements can be adapted when a degradation appears.

The process may comprise one or more steps of selection of said data, parameters and values for storing said data, parameters and values corresponding to meteorological conditions set by the user.

This serves to detect degradation whose appearance depends on temperature conditions, for example.

At least some of the p parameters may come from a calculation of the ratio of the time integral of the power at MPP to the product of the efficiency with the time integral of the received irradiance according to daily cycles.

This calculation is used to provide parameters smoothed over one day.

At least some of the steps of calculation, tracing and displaying comprise a trace of curves of the slope dI/dV− as a function of the slope dI/dV+ for the points measured throughout said measurement steps.

The process may comprise a step of searching for degradation of the module and the case of degradation, a step of searching for a cause of degradation, for which said search is done by the comparison of the offset of a curve obtained from the measurements from a set of model curves for various degradation modes.

The process may comprise a step of displaying a cause of degradation.

The process may comprise the comparison of one or more measured parameter curves with a degradation limit indicator beyond which an anomaly detection alert is sent to an operator.

The present disclosure further relates to a device for maximum power point tracking of a photovoltaic module comprising a case provided with a display screen and a processor and configured for implementing the disclosed process and displaying the resulting curves.

Said case is inserted between one or more modules and a direct current/alternating current converter.

Said case may comprise a communication module with external connection towards a remote processor of a monitoring system configured for programming notably the types of measurements and the periodicity of these measurements in the digital processor or retrieving data from measurements done by said case and for sending information to an operator about the status of the modules and alerts upon anomaly detection.

The present disclosure further relates to a computer program comprising instructions for implementing the process described above when this program is executed by a digital processor.

Finally the present disclosure relates to a computer-readable nonvolatile recording medium on which a program is stored for implementing the process when this program is executed by a digital processor.

### BRIEF DESCRIPTION OF THE DRAWINGS

Other characteristics, details and advantages will appear upon reading the following detailed description and analyzing the attached drawings, on which:

FIG. 1 shows a conventional curve J(V) of a photovoltaic cell;

FIG. 2 shows the curve from FIG. 1 with the measurement points according to an aspect of the present disclosure;

FIG. 3 shows a logic diagram describing the steps of an embodiment of the present disclosure.

FIG. 4 shows theoretical degradation curves according to several degradation mechanisms and a measured degradation curve for a module;

FIG. 5 represents a simple implementation of a case practicing the process from the present disclosure.

### DETAILED DESCRIPTION

The maximum power point tracking device with degradation monitoring from the present disclosure called MPPT-DM (for Maximum Power Point Tracking with Degradation Monitoring) is designed for tracking in situ and in real time the degradation of photovoltaic modules and identifying the mechanisms involved to be able to plan necessary improvements or even detect anomalies early anticipating the replacement of the defective modules during a favorable window and thus avoiding unavailability. With associated mechanisms, this applies both at the scale of the cell and of the module.

Currently new technologies, such as perovskite cells, which could be coupled, or not, with other cells like silicon, are undergoing development. Based on different materials than the silicon cell, it is crucial to implement monitoring of the degradation under real conditions and more specifically to consider the causes in order to be able to act or anticipate upcoming module installations. Such monitoring finally serves to better predict the lifetime of the installation and the production thereof.

During the life of the module, the maximum power point thereof develops continuously. In order to optimize the production, maximum peak power tracking MPPT devices are conventionally used to continuously seek the optimal operation point of the module, serving to maximize the energy production.

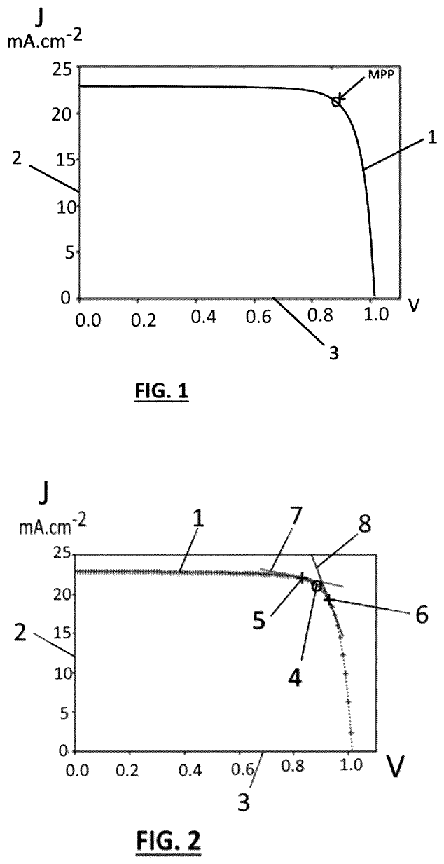

In the case of normal operation from the prior art, the curve 1 from FIG. 1 represents the current density J 2, function of the voltage V 3 of a cell. The tracking devices continuously seek to maintain the power at the maximum power point MPP for the cells and the modules. Equivalently it is also known to use the current/voltage curve of the module for implementing the MPP tracking function and in the case of tracking a module or several modules, according to the present disclosure, the current/voltage I (V) curve is used for the calculations.

The tracking device from the present invention is for its part designed both for getting the MPP and also for regularly analyzing the development of various electrical parameters associated with the current-voltage characteristics of the modules. To do that, the module is going to be specifically driven on the basis of the tracking device thereof in order to recover the parameters in terms of current-voltage necessary for identifying the degradation path in progress and the underlying mechanisms. These parameters are measured by specific sweeping of the current-voltage characteristic at defined moments of the life of the module and serve to deduce from them, by comparison with data modeled for this same module, the degradation paths and also the causes thereof in terms of mechanism. To do this the present disclosure proposes a specific algorithm for control of the photovoltaic module tracking device (MPP tracking device).

The solution and the various steps are detailed below.

Conventionally, according to uniform time steps δt₀, for example every 10 seconds, the tracking device measures around the MPP in order to continuously monitor this maximum power point and to maximize the produced power.

However, according to the present disclosure, measurements are made around the MPP by the tracking device which are going to move the operating point away from the maximum power point. These measurements may be done at δt₁=n₁δt₀ intervals, where n may be selected for example between 100 and 10,000 or more or even be variable as a function of the age of the module, for example decreasing with the age of the module. These simple measurements serve to identify an estimate of the slopes of the current/voltage curve around the MPP. FIG. 2 shows these measurements around the MPP 4 for current/voltage density curve J(V) 1 always in the case of a single cell for remaining consistent with FIG. 1. In this example, beyond the measurement of the MPP, a first measurement is done by offsetting the operating point of the cell to a voltage V_{MPP}−α, for example V_{MPP}−50 mV at point 5 and to V_{MPP}+β for example V_{MPP}+50 mV at point 6 which respectively gives the tangent slope 7 dJ/dV− for the point at V_{MPP}−50 mV and the tangent slope 8 dJ/dV+ for the point at V_{MPP}+50 mV. This interval around the maximum power point may be adjusted for a given photovoltaic installation according to the technology of the modules. For example, points at V_{MPP}−100 mV and at V_{MPP}+50 mV or points at V_{MPP}−100 mV and at V_{MPP}+100 mV may be chosen. There again, in the case of one or more modules according to the present disclosure, the measurements are done on the curve I(V), with V, module voltage and I module current, homothetic curve of the J(V) curve for which V is the cell voltage and J the current density of the cell. In this case, V_{MPP}, α and β will be adapted to the number of cells placed in series.

Subsequently, at a time step δt₂=n₂δt₀>>δt₁, selected for a small impact on electricity production, for example such that the measurements are done once per day or month, a larger number of points from the current-voltage curve are required on the I(V) curve, possibly with points distributed over the full voltage range [0, Voc], in order to generate sufficient information in order to get the parameters Jsc: short-circuit current density (or short-circuit current for several cells), Voc: open-circuit voltage, FF: form factor describing the shape of the curve. Then by comparison with a model, for example a diode model, the parameters Rs series resistance, Rsh parallel resistance of the module, I0 diode saturation current, and N ideality factor result.

The number of points measured over the voltage range [0, Voc] is evaluated specifically to allow having sufficient information for feeding the model while minimizing the acquisition time and the impact on production.

Thus a set of data E1=[MPP, dI/dV+ or dJ/dV+, dI/dV− or dJ/dV−] are obtained at regular time intervals δt₁ and another set of data E2=[N, Voc, FF, Rs, Rsh, I0, N] are obtained at regular time intervals δt₂.

The data collected could undergo preprocessing for selecting those having been measured under meteorological conditions set by the user (temperature, irradiance, etc.). For example, only the measurements done under conditions near STC standard data (1000 W·m⁻², 25° C.) may be extracted.

Alternatively, a step of normalization of the data collected under different meteorological conditions may be implemented so that the data can still be used. The second method, for which no prior data selection is necessary, consists of calculating for each daily cycle the ratio of the time integral of the power at MPP to the product of the efficiency times the time integral of the received irradiance.

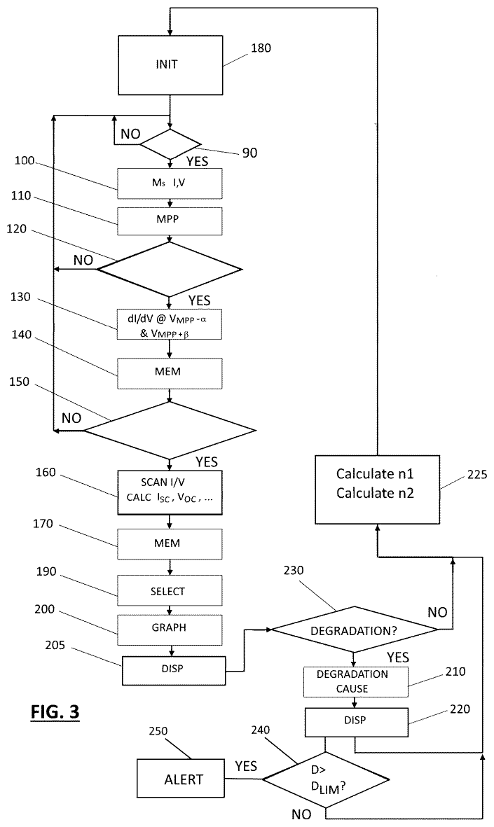

Finally, the data received may be compared to simulation results, which make it possible to know the characteristics of the module (spectral response, electrical behavior, optical and thermal behavior), and by using physical models called derivative-diffusion models, for determining the behavior in the case of the presence of different degradation mechanisms. A finer optimization of this analysis may be done by playing for example with α, β, δt₁ ou δt₂. The process previously described is summarized in FIG. 3.

In step 180, the values t=0, n₁=k1, n₂=k2, α=α₀, β=β₀ are initialized.

In steps 100 and 110, the traditional operating point and positioning measurements at MPP are done.

At step 120, a test is done for verifying whether the moment δt₁=n₁·δt₀ is reached.

If this is not the case, a return to waiting for time interval T+T+δt₀ 90 is done.

If the moment δt₁=n₁δt₀ is reached, a measurement 130 of parameters I and V and dI/dV is done for the offset points at V_{MPP}−α and V_{MPP}+β on the I(V) curve above and below the MPP point and the MPP, dI/dV+, dI/dV− data are stored in step 140.

At step 150, a test is done to determine whether the moment δt₂=n₂δt₀ is reached.

If this is not the case, a return to waiting for time interval 90 is done.

If this is the case, a complete measurement of the values of I and V over all the curve I(V) is done and the parameters Jsc, Voc, FF, Rs, Rsh, I0, N are calculated in step 160, and then the measurements are stored. Additionally, the following parameters may also be measured then used for the analysis of the degradation (in form of derivatives): d[performance and degradation indicator]/d[site meteorological data]. With, for example, the following data for “performance and degradation indicator”: Efficiency, Jsc, Voc, Impp, Vmpp, FF, Rs, Rsh, dI/dV+, dI/dV−; and for “meteorological data,” the following data from the use within the system of dedicated meteorological sensors: humidity, temperature of the environment and the modules, wind speed, pressure, UV index, Irradiance.

The process is repeated by resetting the time counter to zero and setting the values of n₁ and n₂.

In step 225 for example, the values of n₁ and/or n₂ may be modified during said monitoring in order to take into account a possible degradation of the panels to be monitored. These values may in particular be reduced when detecting a degradation or increased if there is no detection of changes in the degradation. The values n₁ and n₂ may in particular be changed with each loop of the algorithm.

In parallel, the data values are selected in step 190, for example for retaining measurements corresponding to set meteorological conditions and for the data curves (up to

$$( \begin{matrix}p \\ 2\end{matrix} )$$

for p parameters measured) are traced with superposition of the measured data and calculated for comparing the characteristics of the module in real time with the theoretical behavior in the case of the presence of different degradation mechanisms.

Should a degradation be detected in the test 230, said curves are analyzed in step 210 to look for a cause of degradation and the result thereof is displayed in step 220.

The test 230 may be a comparison of calculated curves with theoretical curves for types of degradation.

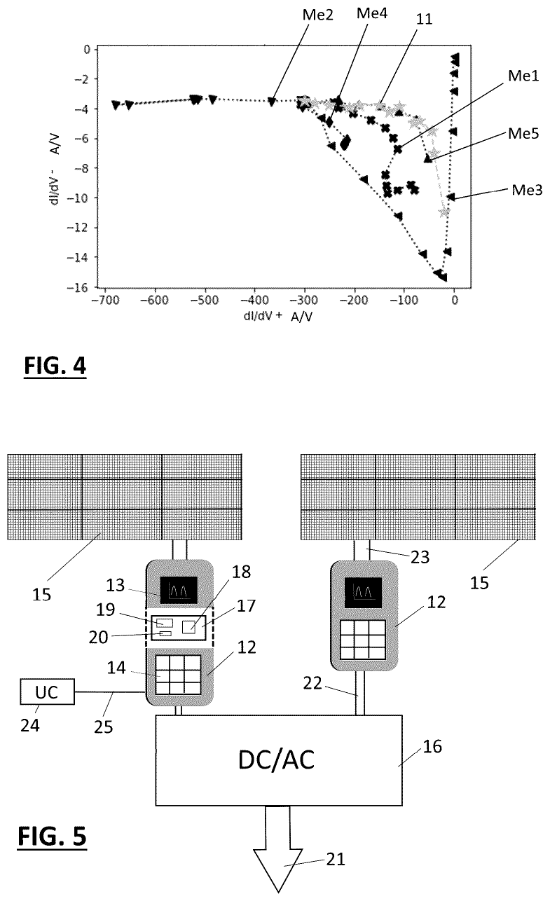

An illustrative example of determination of the degradation path for a perovskite module (monojunction) is shown in FIG. 4. In this example, the curve dI/dV− (the slope at V_{MPP}−α) is traced, compared to dI/dV+ (the slope at V_{MPP}+β). The points for measurement 11 done at given intervals throughout the use of the panel are superposed on possible degradation curves according to various degradation causes: Me1, degradation of the hole transfer layer (“HTL degradation”); Me2, degradation of the interface between hole transfer layer and perovskite (“PVK/HTL interface defects); Me3, degradation of the perovskite layer (“PVK defects”); Me4, degradation of the interface between electron transport layer and perovskite (“PVK/ETL interface defects”); Me5, degradation of the electron transport layer (“ETL degradation”).

This determination can still be generalized to any module type.

Similar curves representing other parameters, one as a function of the other, resulting from sets of measured and calculated data may be traced and used (up to (p/2) for p measured parameters). The comparison of the deviation of the set of curves resulting from the measurements from the set of curves modeled on various degradation modes next allows deducing the mechanisms in play.

Once the degradation modes are determined, the process may comprise the comparison 240 of one or more degradation mechanisms D with a degradation limit indicator D_{LIM} beyond which an anomaly early detection alert 250 is sent to an operator.

The collected data may be analyzed according to distinct and/or selected time windows; the analysis may then be used to determine the mechanism responsible for the degradation during these windows. One may for example imagine that a mechanism degrading the performance in winter would not be active under meteorological conditions in summer, and that another mechanism would then be decisive. The analysis would therefore be distinct for these seasons.

The data collected and analyses done may be applied to the entire photovoltaic installation, or a distinction may be made between the chains connected to the different inputs of the tracking device(s).

It is possible to consider some sets of parameters such as E1, E2, E3 [Jsc, Voc, FE] or even E1+E3 alone or accumulated.

The tracking system called “MPPT-DM tracking device” from the present disclosure which allows tracking of degradation mechanisms is shown in FIG. 5 in the form of a case 12. In this example two panels 15 are each connected to a case 12 from the present disclosure, where both cases are connected to a direct current/alternating current converter 16 connected to a grid 21.

The case 12 which replaces a conventional MPP tracking case comprises power inputs 23 for connection to the panel and power outputs 22 towards the converter and comprises an electronics card 17 provided with a digital processor 18 such as a microcontroller provided with digital and analog inputs/outputs for example, memory 19 associated therewith, further provides a display 13 with which to consult the results, possibly a keyboard 14, and/or a communication module 20 with external connection 25 towards a remote processor 24 configured for example for programming in particular in the digital processor 18 the types of measurements and the periodicity of these measurements or retrieving measurement data taken by said case and transmitting information on the status of the modules and anomaly detection alerts to an operator.

The digital processor 18 and the memory thereof are configured for implementing the maximum power tracking of the module(s) and the steps of the process from the present disclosure. The system is adaptable to any photovoltaic module type.

According to the example, the case is inserted between photovoltaic modules such as photovoltaic panels and a direct current/alternating current (DC/AC) converter itself connected to an alternating grid. As a variant, the tracking device may be integrated in the inverter case and be included in a “photovoltaic inverter” offering.

The tracking device could further be used with or without the degradation analysis function.

The present disclosure may be applied to various types of modules independent of their technology, the silicon and perovskite technologies being cited as nonlimiting examples, and may relate to a photovoltaic field comprising more than two panels and notably may comprise several rows of panels each connected to an MPPT-DM device such as described.

1-16. (canceled)

17. A method for maximum power point tracking of at least one photovoltaic module, comprising, according to a periodicity δt₀, of the I/V operating point measurements of said module and positioning of said operating point at the maximum power point MPP thereof, comprising a monitoring of the degradation of said module, where said monitoring comprises:
according to a periodicity n₁δt₀ with n₁>1 constant or variable, steps of measurement of the parameters I and V of said module for points offset in voltage V_{MPP}+α and V_{MPP}−β over the curve I(V) relative to the maximum power point MPP, a calculation of the slope dI/dV+ at the point V_{MPP}+α and of the slope dI/dV− at the point V_{MPP}−β and recording of said data along with the MPP;
according to a periodicity n₂δt₀ with n₂≥n₁ of steps of measurement of values of I and V by sweeping the curve I(V) and calculation of parameters (Jsc, Voc, FF, Rs, Rsh, I0, N) of said module and storage of said parameters and values;
one or several steps of calculation, tracing and display of
$$( \begin{matrix}p \\ 2\end{matrix} )$$
curves of data pairs based on p measured and calculated parameters;
one or more steps of detecting degradation from said measured and calculated parameters.

18. The method according to claim 17, wherein at least some of said p parameters come from calculation of derivatives d[X]/d[Y] with X=[performance and degradation indicator] and Y=[meteorological data for the site], said performance and degradation indicator comprising: Efficiency, Jsc, Voc, Impp, Vmpp, FF, Rs, Rsh, dI/dV+, and dI/dV−, and said “meteorological data” comprising: humidity, environmental and module temperature, wind speed, pressure, UV index, and irradiance by means of dedicated meteorological sensors communicating, and the display of said derivatives.

19. The method according to claim 17, wherein the values of α and β are adjusted according to the number of cells of said module included in said measurement steps.

20. The method according to claim 17, comprising a modification of the values n₁ and/or n₂ during said monitoring.

21. The method according to claim 20, wherein the values n₁ and/or n₂ are reduced during detection of a degradation and in the absence of detection of development of the degradation, the values n₁ and/or n₂ are increased with each loop of the algorithm.

22. The method according to claim 17, comprising one or more steps of selection of said data, parameters and values for storing said data, parameters and values corresponding to meteorological conditions set by the user.

23. The method according to claim 17, wherein at least some of the p parameters come from a calculation of the ratio of the time integral of the power at MPP to the product of the efficiency with the time integral of the received irradiance according to daily cycles.

24. The method according to claim 17, wherein at least some of the steps of calculation, tracing and displaying comprise a trace of curves of the slope dI/dV− as a function of the slope dI/dV+ for the points measured throughout said measurement steps.

25. The method according to claim 17, comprising a step of searching for degradation of the module and the case of degradation, a step of searching for a cause of degradation, for which said search is done by the comparison of the offset of a curve obtained from the measurements from a set of model curves (Me1, Me2, Me3, Me4, Me5) for various degradation modes.

26. The method according to claim 25, comprising a step of displaying a cause of degradation.

27. The method according to claim 25, comprising a comparison of one or more measured parameter curves with a degradation limit indicator beyond which an anomaly detection alert is sent to an operator.

28. A device for maximum power point tracking of a photovoltaic module comprising a case provided with a display screen and a processor, and configured for implementing a method for maximum power point tracking of at least one photovoltaic module, comprising, according to a periodicity δt₀, of the I/V operating point measurements of said module and positioning of said operating point at the maximum power point MPP thereof,
comprising a monitoring of the degradation of said module, where said monitoring comprises:
according to a periodicity n₁δt₀ with n₁>1 constant or variable, steps of measurement of the parameters I and V of said module for points offset in voltage V_{MPP}+α and V_{MPP}−β over the curve I(V) relative to the maximum power point MPP, a calculation of the slope dI/dV+ at the point V_{MPP}+α and of the slope dI/dV− at the point V_{MPP}−β and recording of said data along with the MPP;
according to a periodicity n₂δt₀ with n₂≥n₁ of steps of measurement of values of I and V by sweeping the curve I(V) and calculation of parameters (Jsc, Voc, FF, Rs, Rsh, I0, N) of said module and storage of said parameters and values;
one or several steps of calculation, tracing and display of
$$( \begin{matrix}p \\ 2\end{matrix} )$$
curves of data pairs based on p measured and calculated parameters;
one or more steps of detecting degradation from said measured and calculated parameters.

29. The device of claim 28, wherein at least some of said p parameters of said method come from calculation of derivatives d[X]/d[Y] with X=[performance and degradation indicator] and Y=[meteorological data for the site], said performance and degradation indicator comprising: Efficiency, Jsc, Voc, Impp, Vmpp, FF, Rs, Rsh, dI/dV+, and dI/dV−, and said “meteorological data” comprising: humidity, environmental and module temperature, wind speed, pressure, UV index, and irradiance by means of dedicated meteorological sensors communicating, and the display of said derivatives.

30. The device of claim 28, wherein the values of α and β of said method are adjusted according to the number of cells of said module included in said measurement steps.

31. The device of claim 28, wherein said method comprises a modification of the values n₁ and/or n₂ during said monitoring.

32. The device of claim 31, wherein the values n₁ and/or n₂ are reduced during detection of a degradation and in the absence of detection of development of the degradation, the values n₁ and/or n₂ are increased with each loop of the algorithm.

33. The device of claim 28, wherein the method comprises one or more steps of selection of said data, parameters and values for storing said data, parameters and values corresponding to meteorological conditions set by the user.

34. The device of claim 28, wherein at least some of the p parameters come from a calculation of the ratio of the time integral of the power at MPP to the product of the efficiency with the time integral of the received irradiance according to daily cycles.

35. The device of claim 28, wherein at least some of the steps of calculation, tracing and displaying comprise a trace of curves of the slope dI/dV− as a function of the slope dI/dV+ for the points measured throughout said measurement steps.

36. The device of claim 28, wherein the comprising a step of searching for degradation of the module and the case of degradation, a step of searching for a cause of degradation, for which said search is done by the comparison of the offset of a curve obtained from the measurements from a set of model curves (Me1, Me2, Me3, Me4, Me5) for various degradation modes.

37. The device of claim 36, comprising a step of displaying a cause of degradation.

38. The device of claim 37, comprising a comparison of one or more measured parameter curves with a degradation limit indicator beyond which an anomaly detection alert is sent to an operator.

39. The device of claim 28, wherein said case is inserted between one or more modules and a direct current/alternating current converter.

40. The device of claim 28, wherein said case comprises a communication module with external connection towards a remote processor a monitoring system configured for programming notably the types of measurements and the periodicity of these measurements in the digital processor or retrieving data from measurements done by said case and for sending information to an operator about the status of the modules and alerts upon anomaly detection.

41. A computer program comprising instructions for implementing the method according to claim 16, when this program is executed by a digital processor.

42. A computer-readable nonvolatile recording medium on which a program is stored for implementing the method according to claim 16 when this program is executed by a digital processor.
